(19) United States
(12) Patent Application Publication
(10) Pub. No.: US 2024/0167190 A1
(43) Pub. Date: May 23, 2024

(54) INGOT GROWTH APPARATUS AND METHOD FOR CONTROLLING PRELIMINARY CRUCIBLE OF INGOT GROWTH APPARATUS

(71) Applicant: HANWHA SOLUTIONS CORPORATION, Seoul (KR)

(72) Inventors: Keun Ho KIM, Seoul (KR); Jin Sung PARK, Seoul (KR); Young Min LEE, Seoul (KR); Han Woong JEON, Seoul (KR)

(73) Assignee: HANWHA SOLUTIONS CORPORATION, Seoul (KR)

(21) Appl. No.: 18/551,066

(22) PCT Filed: Jun. 23, 2022
(86) PCT No.: PCT/KR2022/008919

§ 371 Date: Sep. 18, 2023

(30) Foreign Application Priority Data
Jun. 25, 2021 (KR) 10-2021-0083428

(51) Int. Cl. C30B 15/12; C30B 15/02; C30B 15/14; C30B 15/20; C30B 29/06

(52) U.S. Cl. CPC C30B 15/12; C30B 15/02; C30B 15/14; C30B 15/20; C30B 29/06

(57) ABSTRACT

An ingot growth apparatus according to an embodiment of the present invention comprises: a growth furnace having a main crucible which is disposed within the growth furnace and holds molten silicon therein in order to grow an ingot; a preliminary melting part having a preliminary crucible which is supplied with a solid silicon material, melts the solid silicon material, and supplies the molten silicon to the main crucible; a temperature detection sensor which is disposed above the preliminary melting part and detects the temperature of the solid silicon material or molten silicon held in the preliminary melting part; and a control part which controls supply of the molten silicon from the preliminary crucible to the main crucible on the basis of the temperature detected by the temperature detection sensor.

### CROSS-REFERENCE TO RELATED APPLICATION

This application claims priority to and the benefit of Korean Patent Application No. 10-2021-0083428, filed on Jun. 25, 2021, the disclosure of which is incorporated herein by reference in its entirety.

### TECHNICAL FIELD

The present invention relates to an ingot growth apparatus and a method for controlling molten silicon in a preliminary crucible of the ingot growth apparatus.

### BACKGROUND ART

Single-crystal silicon is used as a basic material for most semiconductor components, and these materials are manufactured as single crystals with high purity, and one of the manufacturing methods thereof is the Czochralski method.

In the Czochralski crystal method, a solid silicon material is placed in a crucible in a chamber, and the susceptor is heated by using a heating element to melt the silicon. In addition, when a single crystal seed is pulled up through a wire in an upward direction while rotating in a state of being in contact with this molten silicon, an ingot having a predetermined diameter is grown through a crown process in which the diameter is increased to approach the target diameter of the ingot.

The Continuous Czochralski method (CCz), which is one of the Czochralski methods, is a method of continuously injecting solid polysilicon or molten silicon into the crucible to continuously grow an ingot while replenishing the consumed molten silicon.

However, in the process of injecting solid polysilicon into the crucible, a phenomenon occurs in which the molten silicon splashes. In addition, when the molten silicon splashes, waves are generated in the molten silicon, and there is a problem in that the single crystal yield of the ingot is lowered.

In addition, while the solid polysilicon is injected into the crucible, a rapid temperature change of the molten silicon occurs. Such a temperature change becomes a factor in lowering the single crystal yield of the ingot.

In addition, when some of the solid polysilicon remains even when the molten silicon is injected into the crucible, the solid polysilicon is directly attached to the ingot, thereby reducing the yield and quality of the ingot.

### DISCLOSURE

### Technical Problem

The present invention has been devised to solve the above problems, and is directed to providing an ingot growth apparatus in which solid polysilicon is completely melted and molten silicon is supplied to a crucible, and a method for controlling a preliminary crucible of the ingot growth apparatus.

In addition, the present invention is directed to providing an ingot growth apparatus which is capable of managing the quality and yield of an ingot at certain levels, and a method for controlling a preliminary crucible of the ingot growth apparatus.

### Technical Solution

According to solve the above problems, the ingot growth apparatus according to an exemplary embodiment of the present invention may include a growth furnace having a main crucible which is disposed within the growth furnace and holds molten silicon therein in order to grow an ingot: a preliminary melting part having a preliminary crucible which is supplied with a solid silicon material, melts the solid silicon material, and supplies the molten silicon to the main crucible: a temperature detection sensor which is disposed above the preliminary melting part and detects the temperature of the solid silicon material or molten silicon held in the preliminary melting part: and a control part which controls supply of the molten silicon from the preliminary crucible to the main crucible on the basis of the temperature detected by the temperature detection sensor.

In this case, the preliminary melting part may include a body part which accommodates the preliminary crucible and is formed with a detection hole through which light generated from the temperature detection sensor moves: a heater which is disposed on an inner side surface of the body part and is disposed to be spaced apart from the preliminary crucible to heat the preliminary crucible; and a coil which is accommodated inside the body, is spaced apart from the heater and formed to be wound multiple times to generate a magnetic field, and heats the heater by electromagnetic induction by the magnetic field.

In this case, the coil may include a first coil which is disposed above the heater: and a second coil which is disposed to be spaced apart from the first coil, and the detection hole may be formed between the first coil and the second coil.

In this case, the ingot growth apparatus may further include a heat insulating part which is disposed above the body part, supports the temperature detection sensor and blocks the movement of heat from the body part to the temperature detection sensor, wherein a second detection hole communicating with the detection hole is formed in the heat insulating part.

In this case, the preliminary crucible may include a first sidewall which faces the main crucible: and a second sidewall which is formed on the opposite side of the first sidewall, and the temperature detection sensor may be disposed closer to the second sidewall than to the first sidewall based on an angle inclined with respect to a lower side of the body part.

In this case, the preliminary melting part may further include a contamination prevention part which is inserted into and fixed to the detection hole.

In this case, the control part may supply a solid silicon material to the preliminary crucible for a predetermined number of times.

In this case, when the temperature detected by the temperature detection sensor is higher than the temperature of the molten silicon, the control part may control the melting time of the preliminary crucible such that the preliminary crucible melts the solid silicon material, and when the temperature detected by the temperature detection sensor corresponds to the temperature range of molten silicon, the control part may control to supply a solid silicon material to the preliminary crucible.

In this case, when the temperature detected by the temperature detection sensor corresponds to the temperature range of the molten silicon while a solid silicon material is supplied to the preliminary crucible for a predetermined number of times, the control part may control to supply molten silicon of the preliminary crucible to the main crucible.

In addition, the method for controlling a preliminary crucible of an ingot growth apparatus according to an exemplary embodiment of the present invention is a method for controlling a preliminary crucible for supplying molten silicon to a main crucible of an ingot growth apparatus, and the method may include a solid silicon supplying step of supplying a quantitative amount of a solid silicon material to the preliminary crucible: a temperature detection step of detecting a temperature of the molten silicon or the solid silicon material accommodated in the preliminary crucible: a holding time determination step of determining a heating time of the preliminary crucible based on the temperature measured by the temperature sensor; a solid silicon supply number determination step of determining whether to supply the solid silicon material to the preliminary crucible for a plurality of times based on the temperature measured by the temperature detection sensor; and a liquid silicon supplying step of supplying silicon melted in the preliminary crucible to the main crucible.

In this case, the solid silicon supply number determination step may determine whether the temperature detected by the temperature detection sensor corresponds to the temperature range of the molten silicon, while a solid silicon material is supplied to the preliminary crucible for a predetermined number of times.

### Advantageous Effects

In the ingot growth apparatus and the method for controlling a preliminary crucible of the ingot growth apparatus according to an exemplary embodiment of the present invention, based on the temperature detected by a temperature detection sensor, it is determined whether the solid silicon material supplied to the preliminary crucible is melted, and by supplying molten silicon to the crucible, it is possible to prevent unmelted solid silicon material from being supplied to the crucible.

In addition, since it reduces the time required for the molten silicon to be accommodated in the preliminary crucible more than necessary, the ingot manufacturing cost can be reduced by shortening the ingot manufacturing process time.

### DESCRIPTION OF DRAWINGS

FIG. 1 is a view schematically showing an ingot growth apparatus according to an exemplary embodiment of the present invention.

FIG. 2 is a block diagram of the ingot growth apparatus according to an exemplary embodiment of the present invention.

FIG. 3 is a view showing a preliminary melting part and a temperature detection sensor of FIG. 1.

FIG. 4 is a perspective view schematically showing a coil and a detection hole of FIG. 2.

FIG. 5 is a plan view schematically showing a coil and a detection hole of FIG. 2.

FIG. 6 is a view showing how a temperature detection sensor measures the temperature of a solid silicon material.

FIG. 7 is a diagram showing the position of a temperature detection sensor.

FIG. 8 is a flowchart showing a method for controlling molten silicon by a control part.

FIG. 9 is a graph showing the temperature detected by the temperature detection sensor.

FIG. 10 is a view showing the preliminary melting part of an ingot growth apparatus according to another exemplary embodiment of the present invention.

| | |
|---|---|
| 100: Ingot growth apparatus | 110: Growth furnace |
| 120: Main crucible | 140: Preliminary melting part |
| 142: Preliminary crucible | 160: Temperature detection sensor |
| 190: Control part | |

### MODES OF THE INVENTION

Hereinafter, various exemplary embodiments will be described in more detail with reference to the accompanying drawings. The exemplary embodiments according to the present invention may be modified in various forms. A specific exemplary embodiment may be illustrated in the drawings and may be described in detail in the detailed description. However, the specific exemplary embodiment disclosed in the accompanying drawing is merely provided for easy understanding of various exemplary embodiments. Accordingly, it should be understood that the technical spirit is not limited by the specific exemplary embodiment disclosed in the accompanying drawing, but includes all equivalents or alternatives included in the spirit of and the technical scope of the present invention.

Terms including an ordinary number, such as first and second, are used for describing various constituent elements, but the constituent elements are not limited by the terms. The above terms are used only to discriminate one component from the other component.

In the exemplary embodiments of the present invention, it should be understood that terminology such as “include” or “have” indicates that a feature, a number, a step, an operation, a component, a part or the combination thereof described in the exemplary embodiments of the present invention is present, but does not exclude a possibility of presence or addition of one or more other features, numbers, steps, operations, components, parts or combinations, in advance. It should be understood that, when it is described that an element is “coupled” or “connected” to another element, the element may be directly coupled or directly connected to the other element, or coupled or connected to the other element through a third element. In contrast, when it is described that an element is “directly coupled” or “directly connected” to another element, it should be understood that no element is present therebetween.

Meanwhile, “module” or” “part” for components used in the exemplary embodiments of the present invention performs at least one function or operation. In addition, “module” or “part” may perform a function or an operation by software or a combination of hardware and software. In addition, a plurality of “modules” or a plurality of “parts” excluding “module” or “part” which has to be executed in a specific hardware or is executed in at least one processor may be integrated as at least one module. A singular expression may include a plural expression if there is no clearly opposite meaning in the context.

Further, in the description of the exemplary embodiments of the present invention, the detailed description of known configurations or functions incorporated herein will be contracted or omitted, when it is determined that the detailed description may make the gist of the present invention unclear.

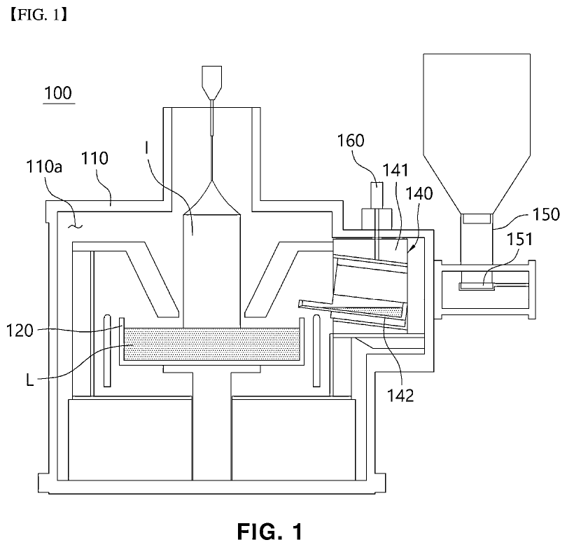

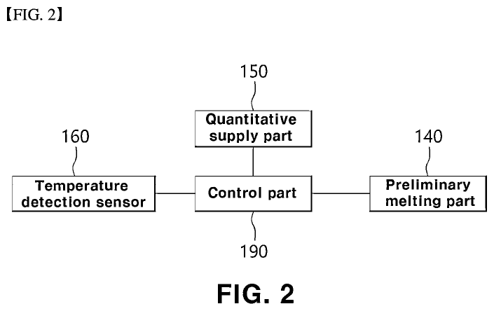

FIG. 1 is a view schematically showing an ingot growth apparatus according to an exemplary embodiment of the present invention, and FIG. 2 is a block diagram of the ingot growth apparatus according to an exemplary embodiment of the present invention.

Referring to FIGS. 1 and 2, the ingot growth apparatus 100 according to an exemplary embodiment of the present invention includes a growth furnace 110, a main crucible 120, a preliminary melting part 140, a quantitative supply part 150, a temperature detection sensor 160 and a control part 190.

The growth furnace 110 has an inner space 110a that is maintained in a vacuum state, and an ingot I is grown in the inner space 110a.

The growth furnace 110 is provided with a vacuum pump (not illustrated) and an inert gas supply part (not illustrated). The vacuum pump may maintain the inner space 110a in a vacuum atmosphere. In addition, the inert gas supply part supplies an inert gas to the inner space 110a. The inert gas may be, for example, argon (Ar).

The main crucible 120 is accommodated in the inner space 110a of the growth furnace 110. The main crucible 120 may accommodate molten silicon M.

In addition, the main crucible 120 is made of a quartz material. However, the main crucible 120 is not limited to being made of a quartz material, and it may be made of various materials that have heat resistance at a temperature of about 1,400° C. or higher and withstand rapid temperature changes.

In this case, when the single crystal seed is pulled upward in a state of being in contact with the molten silicon L contained in the main crucible 120, the diameter the ingot I having a predetermined diameter is grown along a direction in which the ingot I is pulled through a crown process in which the diameter of the ingot is increased to approach the target diameter of the ingot I.

The growth furnace 110 is provided with the susceptor (not illustrated) which is formed to surround an outer side surface of the main crucible 120. The susceptor supports the main crucible 120. The inner side surface of the susceptor is formed in a shape corresponding to the outer side surface of the main crucible 120. The susceptor is made of a graphite material. In addition, the susceptor is not limited to being made of a graphite material, and it may be made of various materials having strong heat resistance and conductive properties.

Accordingly, even if the main crucible 120 is made of a quartz material and is deformed at a high temperature, the susceptor surrounds and supports the main crucible 120 so as to maintain a state of accommodating the molten silicon M.

In addition, a heating part for heating the susceptor is provided in the growth furnace 110. The heating part receives electric power and generates electromagnetic induction to heat the susceptor. In addition, the heat of the susceptor is transferred to the main crucible 120. In addition, the heating part is not limited to being implemented in an induction heating method, and it may be implemented in a resistance heating method in which electric power is supplied and heat is directly generated.

The preliminary melting part 140 receives the solid silicon material and melts the same into molten silicon. In addition, the preliminary melting part 140 includes a body part 141 which accommodates a preliminary crucible accommodating molten silicon.

In this case, the preliminary crucible 142 is made of a quartz material. However, the preliminary crucible 142 is not limited to being made of a quartz material, and it may be made of various materials that have heat resistance at a temperature of about 1,400° C. or higher and withstand rapid temperature changes.

In addition, the preliminary crucible 142 is provided to be positioned between a first position in which the solid silicon material is accommodated and the accommodated solid silicon material is melted, and a second position which is inclined such that the molten silicon is supplied to the main crucible 120. To this end, a preliminary crucible moving module (not illustrated) for moving the position of the preliminary crucible 142 is provided in the preliminary melting part 140. The preliminary crucible moving module tilts one side of the preliminary crucible 142 toward the main crucible 120 and supplies the molten silicon that is accommodated in the preliminary crucible 142 to the main crucible 120. Herein, the side from the preliminary melting part 140 toward the main crucible 120 is referred to as one side, and the opposite side is referred to as the other side. The preliminary melting part 140 will be described in detail with reference to the drawings below.

The quantitative supply part 150 is disposed outside the growth furnace 110. In addition, the quantitative supply part 150 is disposed adjacent to the preliminary melting part 140. The quantitative supply part 150 supplies the solid silicon material to the preliminary crucible 142.

In this case, the quantitative supply part 150 includes a weight measuring part 151 for measuring the weight of the solid silicon material to be supplied to the preliminary crucible 142. In addition, the solid silicon material in a quantitative amount is supplied to the preliminary crucible 142.

The temperature detection sensor 160 is disposed above the preliminary melting part 140. In addition, the temperature detection sensor 160 detects the temperature of the solid silicon material or molten silicon that is accommodated in the preliminary melting part.

In this case, the temperature detection sensor 160 is any one of a heat detection temperature sensor, an infrared temperature sensor or an infrared CCD camera. However, the temperature detection sensor 160 is not limited to a heat sensing temperature sensor, an infrared temperature sensor or an infrared CCD camera, and it may be various temperature measuring devices using electromagnetic waves.

The control part 190 is electrically connected to each of the preliminary melting part 140, the quantitative supply part 150 and the temperature detection sensor 160.

In this case, the control part 190 controls the supply of molten silicon from the preliminary crucible 142 to the main crucible 120, based on the temperature detected by the temperature detection sensor 160. The method of controlling the supply of molten silicon by the control part 190 will be described in detail with reference to the accompanying drawings.

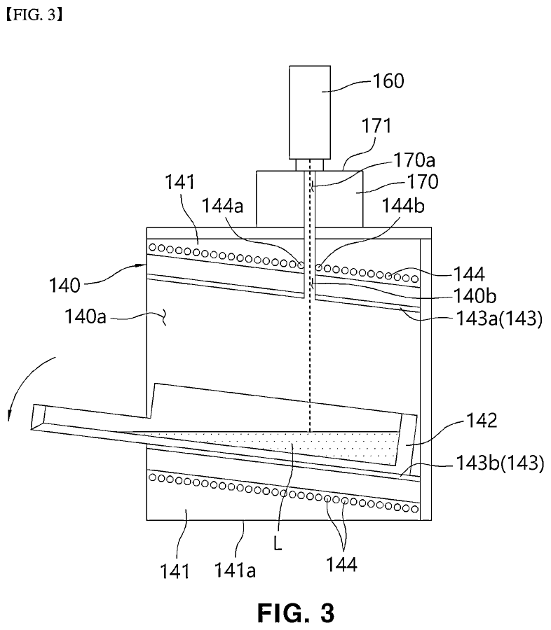

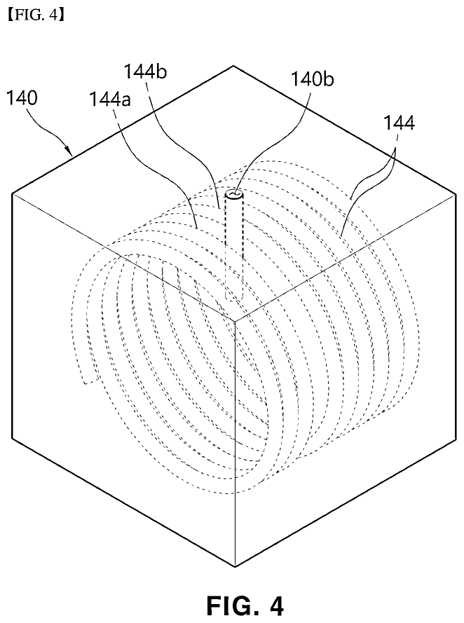

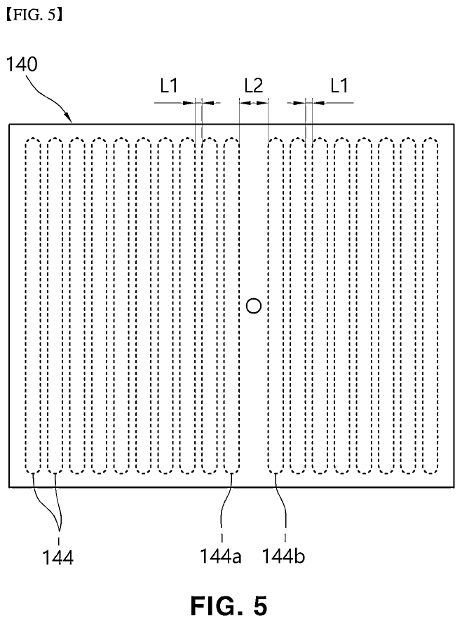

FIG. 3 is a view showing a preliminary melting part and a temperature detection sensor of FIG. 1, FIG. 4 is a perspective view schematically showing a coil and a detection hole of FIG. 2, and FIG. 5 is a plan view schematically showing a coil and a detection hole of FIG. 2.

Referring to FIGS. 3 to 5, the preliminary melting part 140 includes the body part 141 and the preliminary crucible 142, as well as a heater 143 and a coil 144.

First of all, the preliminary crucible 142 is accommodated in the inner space 140a of the body part 141.

In addition, a detection hole 140b through which light generated from the temperature detection sensor 160 moves is formed in the body part 141. Accordingly, the temperature detection sensor 160 detects the temperature of the molten silicon L that is accommodated in the preliminary crucible 142 through the detection hole 140b.

The heater 143 is disposed on an inner side surface of the body part 141. In addition, the heater 143 is disposed to be spaced apart from the preliminary crucible 142. In addition, the heater 143 heats the preliminary crucible 142. In this case, the heater 143 is made of a graphite material. However, the heater 143 is not limited to being made of a graphite material, and it may be made of various materials having electrical conductivity such as metal. The heater 143 includes a first heater 143a which is disposed above the preliminary crucible 142 and a second heater 143b which is disposed below the preliminary crucible 142.

The first heater 143a is disposed farther from the preliminary crucible 142 than the second heater 143b. In this case, the second heater 143b is disposed closer to the preliminary crucible 142 than the first heater 143b such that heat transfer efficiency to the preliminary crucible 142 is improved.

The coil 144 is accommodated inside the body part 141. In addition, the coil 144 is made of a metal material. However, the coil 144 is not limited to a metal material and it may be made of various materials having electrical conductivity.

The coil 144 is spaced apart from the heater 143 and is formed to be wound multiple times. Herein, the coil 144 illustrated in FIG. 4 is only for facilitating understanding of the contents of the invention which is formed to be wound with multiple circuits, and the coil 144 is not limited to a spring shape.

In addition, the coil 144 receives electric power and generates a magnetic field. Accordingly, the coil 144 heats the heater 143 by electromagnetic induction by the magnetic field.

In addition, the coil 144 may be defined as a plurality of coil strands, and the coil 144 is continuously formed with the plurality of coil strands.

In this case, the coil 144 which is composed of the plurality of coil strands includes a first coil 144a which is disposed above the first heater 143a and a second coil 114b which is disposed to be spaced apart from the first coil 144a. In addition, a distance L2 between the first coil 144a and the second coil 144b is longer than a distance L1 between the plurality of other coil strands.

Meanwhile, the detection hole 144b is formed between the first coil 144a and the second coil 144b. Accordingly, the light irradiated from the temperature detection sensor 160 is not interfered by the coil 144 and is irradiated in a direction perpendicular to the surface of the molten silicon L accommodated in the preliminary crucible 142 and then, the temperature detection sensor 160 detects the temperature of the molten silicon L by collecting light reflected from the surface of the molten silicon L.

In addition, a heat insulating part 170 which supports the temperature detection sensor 160 is provided on an upper side of the body part 141.

The heat insulating part 170 blocks the movement of heat from the body part 141 to the temperature detection sensor 160. In this case, a second detection hole 170a which communicates with the detection hole 140b is formed in the heat insulating part 170. Accordingly, while the temperature detection sensor 160 is supported on an upper side surface 171 of the heat insulating part 170, it irradiates light toward a surface of the molten silicon L through the second detection hole 170a and the detection hole 140b.

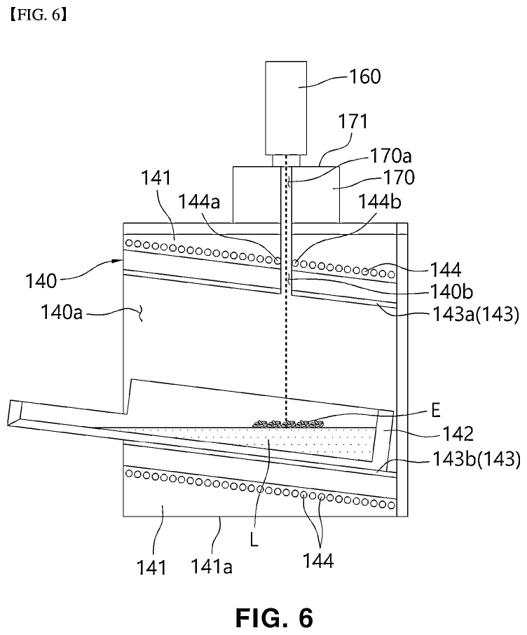

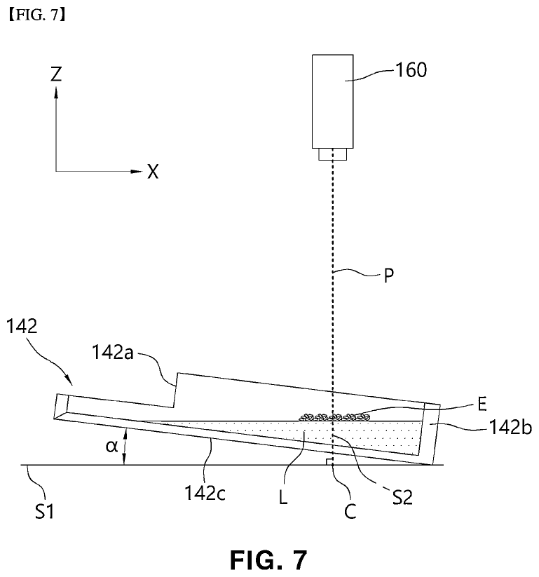

FIG. 6 is a view showing how a temperature detection sensor measures the temperature of a solid silicon material, and FIG. 7 is a diagram showing the position of a temperature detection sensor.

First of all, the solid silicon material E is supplied to the preliminary crucible 142. In this case, the solid silicon material E is not introduced into the preliminary crucible 142 at once, but is supplied to the preliminary crucible 142 for a predetermined number of times to reduce energy consumption for melting the solid silicon material E. Herein, the predetermined number of times may be 3 times, but the present invention is not limited thereto, and it may be variously applied in consideration of the size of the preliminary crucible 142 and power consumption of the coil, such as 2 times or 4 times or more.

In addition, as illustrated in FIG. 6, the temperature detection sensor 160 detects the temperature of the solid silicon material E that is accommodated in the preliminary crucible 142. In this case, in the process of melting the solid silicon material E, the temperature of the solid silicon material E is higher than the general temperature of the molten silicon due to the latent heat of a molten portion of the solid silicon material E.

In addition, the preliminary melting part 140 heats the preliminary crucible 142 through the heater 143 such that the solid silicon E is completely melted.

Meanwhile, as illustrated in FIG. 7, based on an angle α inclined with respect to a lower side 141a of the body part 141, the temperature detection sensor 160 is disposed closer to the second sidewall 142b than the first sidewall 142a. Herein, the angle α is an angle between a first imaginary line S1 that is parallel to the lower side 141a of the body part 141 and the lower side 142c of the preliminary crucible 142.

In this case, an intersection point C of the first imaginary line S1 and the second imaginary line S2 extending from the traveling direction P of the light of the temperature detection sensor 160 is positioned to be closer to the second sidewall 142b than the first sidewall 142a.

Accordingly, even if the solid silicon material E is accommodated in the preliminary crucible 142 inclined at the angle α and positioned to be closer to the second sidewall 142b than the first sidewall 142a, the temperature detection sensor 160 is disposed to correspond to the position of the solid silicon material E to detect the temperature of the solid silicon material E.

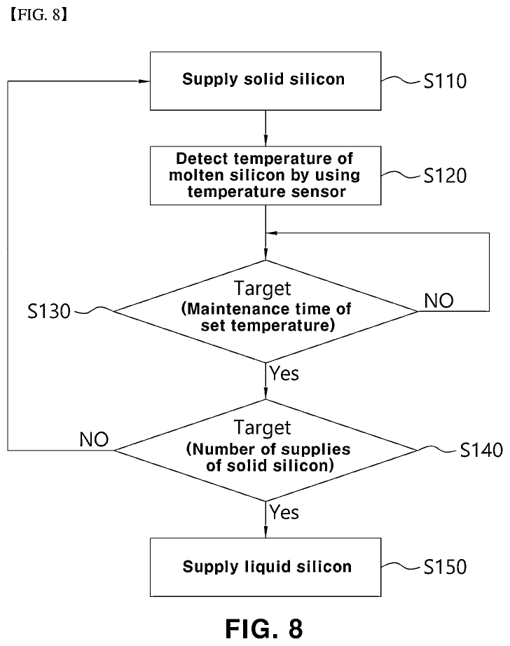

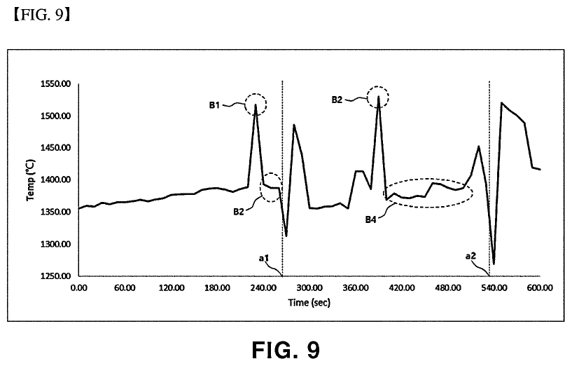

FIG. 8 is a flowchart showing a method for controlling molten silicon by a control part, and FIG. 9 is a graph showing the temperature detected by the temperature detection sensor.

Referring to FIGS. 8 and 9, the method for controlling a preliminary crucible for supplying molten silicon to a main crucible of an ingot growth apparatus according to an exemplary embodiment of the present invention includes a solid silicon supplying step (S110), a temperature detection step (S120), a holding time determination step (S130), a solid silicon supply number determination step (S140) and a liquid silicon supplying step (S150).

In the solid silicon supplying step (S110), as illustrated in FIG. 9, at 0 (sec), the control part 190 controls the preliminary crucible 142 so as to introduce the solid silicon material into the preliminary crucible 142 (refer FIG. 6).

In the temperature detection step (S120), the temperature of the solid silicon material or the molten silicon is detected by using the temperature detection sensor 160 (refer to FIG. 6).

In the holding time determining step (S130), based on the temperature measured by the temperature detection sensor 160, when the measured temperature is higher than the temperature of the molten silicon, the control part 190 continuously heats the preliminary crucible 142 (refer to FIG. 1) to control the melting time of the preliminary crucible 142 such that the solid silicon material is melted. For example, B1 and B2 indicated in FIG. 9 indicate cases where the solid silicon material has not yet melted.

In the solid silicon supply number determination step (S140), based on the temperature measured by the temperature detection sensor 160, when the measured temperature is similar to the temperature of the molten silicon, the control part 190 controls to supply the solid silicon material to the preliminary crucible 142 (refer to FIG. 1). For example, a1 and a2 indicated in FIG. 9 indicate the time during which the solid silicon material is introduced.

In this case, in the solid silicon supply number determination step (S140), the control part 190 controls to supply the solid silicon material to the preliminary crucible 142 for the predetermined number of times. In addition, the solid silicon supply number determination step (S140) determines whether the temperature detected by the temperature detection sensor 160 corresponds to a temperature range of the molten silicon. Herein, the temperature range of the molten silicon generally means the melting point of silicon.

Further, in the liquid silicon supplying step (S150), based on the temperature measured by the temperature detection sensor 160, while the measured temperature is similar to the temperature of the molten silicon and the solid silicon material in the preliminary crucible 142 has been processed for the predetermined number of times, the control part 190 controls to supply the molten silicon accommodated in the preliminary crucible 142 to the main crucible 120.

Meanwhile, as illustrated in FIG. 9, when the solid silicon material is introduced into the preliminary crucible 142 for predetermined times (0, a1, a2), a first holding time B2 for heating the solid silicon material is shorter than a second holding time B4 for heating the solid silicon material. That is, the energy consumption required to melt the solid silicon material of the first holding time B2 is shorter than that of the second holding time B4. In addition, it can be seen that during the second holding time B4, the solid silicon material continues to consume excessive energy even though it has already been melted.

In order to solve this problem, according to an exemplary embodiment of the present invention, the temperature detection sensor 160 measures the temperature of the molten silicon or the solid silicon material and is controlled not to heat the molten silicon more than necessary, and thus, it has the advantage of reducing the energy consumption required to melt the silicon.

In addition, since unnecessary time for heating the molten silicon is reduced, the overall ingot manufacturing time is reduced, and thus, the efficiency of the ingot manufacturing process is improved.

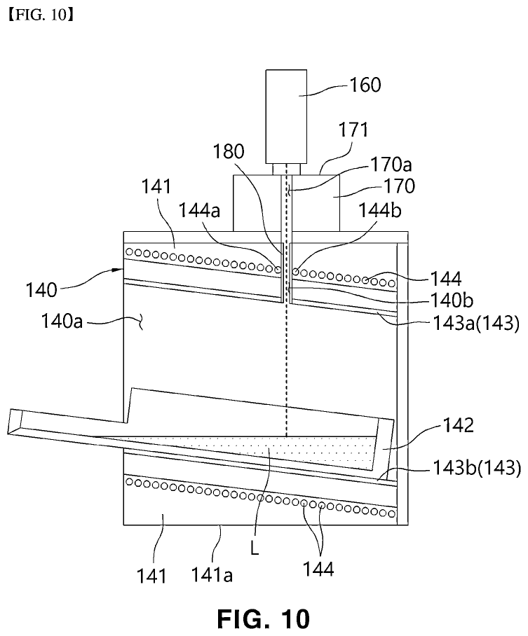

FIG. 10 is a view showing the preliminary melting part of an ingot growth apparatus according to another exemplary embodiment of the present invention.

Referring to FIG. 10, the preliminary melting part 140 is provided with a contamination prevention part 180 which is inserted into and fixed to the detection hole 140b.

The contamination prevention part 180 is formed in a shape corresponding to the detection hole 140b. For example, when the detection hole 140b is formed in a cylindrical shape, the contamination prevention part 180 is also formed in a cylindrical shape. In addition, the contamination prevention part 180 is made of an alumina material. For example, the contamination prevention part 180 is manufactured through a sintering process of alumina. In addition, the contamination prevention part 180 is not limited to being made of an alumina material, and it may be made of various materials having strong heat resistance without induction heating such as ceramic materials.

Accordingly, the contamination prevention part 180 prevents contaminants that are generated in the process of melting the solid silicon material from being attached to the detection hole.

As described above, the preferred exemplary embodiments according to the present invention have been reviewed, and the fact that the present invention can be embodied in other specific forms in addition to the above-described exemplary embodiments without departing from the spirit or scope is a matter that is apparent to those of ordinary skill in the art. Therefore, the exemplary embodiments described above are to be regarded as illustrative rather than restrictive, and accordingly, the present invention is not limited to the above description, but may be changed within the scope of the appended claims and their equivalents.

1. An ingot growth apparatus, comprising:
a growth furnace having a main crucible which is disposed within the growth furnace and holds molten silicon therein in order to grow an ingot;
a preliminary melting part having a preliminary crucible which is supplied with a solid silicon material, melts the solid silicon material, and supplies the molten silicon to the main crucible;
a temperature detection sensor which is disposed above the preliminary melting part and detects the temperature of the solid silicon material or molten silicon held in the preliminary melting part; and
a control part which controls supply of the molten silicon from the preliminary crucible to the main crucible on the basis of the temperature detected by the temperature detection sensor.

2. The ingot growth apparatus of claim 1, wherein the preliminary melting part comprises:
a body part which accommodates the preliminary crucible and is formed with a detection hole through which light generated from the temperature detection sensor moves;
a heater which is disposed on an inner side surface of the body part and is disposed to be spaced apart from the preliminary crucible to heat the preliminary crucible; and
a coil which is accommodated inside the body, is spaced apart from the heater and formed to be wound multiple times to generate a magnetic field, and heats the heater by electromagnetic induction by the magnetic field.

3. The ingot growth apparatus of claim 2, wherein the coil comprises:
a first coil which is disposed above the heater; and
a second coil which is disposed to be spaced apart from the first coil, and
wherein the detection hole is formed between the first coil and the second coil.

4. The ingot growth apparatus of claim 2, further comprising:
a heat insulating part which is disposed above the body part, supports the temperature detection sensor and blocks the movement of heat from the body part to the temperature detection sensor,
wherein a second detection hole communicating with the detection hole is formed in the heat insulating part.

5. The ingot growth apparatus of claim 2, wherein the preliminary crucible comprises:
a first sidewall which faces the main crucible; and
a second sidewall which is formed on the opposite side of the first sidewall, and
wherein the temperature detection sensor is disposed closer to the second sidewall than to the first sidewall based on an angle inclined with respect to a lower side of the body part.

6. The ingot growth apparatus of claim 2, wherein the preliminary melting part further comprises a contamination prevention part which is inserted into and fixed to the detection hole.

7. The ingot growth apparatus of claim 1, wherein the control part supplies a solid silicon material to the preliminary crucible for a predetermined number of times.

8. The ingot growth apparatus of claim 7, wherein when the temperature detected by the temperature detection sensor is higher than the temperature of the molten silicon, the control part controls the melting time of the preliminary crucible such that the preliminary crucible melts the solid silicon material, and
wherein when the temperature detected by the temperature detection sensor corresponds to the temperature range of molten silicon, the control part controls to supply a solid silicon material to the preliminary crucible.

9. The ingot growth apparatus of claim 8, wherein when the temperature detected by the temperature detection sensor corresponds to the temperature range of the molten silicon while a solid silicon material is supplied to the preliminary crucible for a predetermined number of times, the control part controls to supply molten silicon of the preliminary crucible to the main crucible.

10. A method for controlling a preliminary crucible of an ingot growth apparatus which is a method for controlling a preliminary crucible for supplying molten silicon to a main crucible of an ingot growth apparatus, the method comprising:
a solid silicon supplying step of supplying a quantitative amount of a solid silicon material to the preliminary crucible;
a temperature detection step of detecting a temperature of the molten silicon or the solid silicon material accommodated in the preliminary crucible;
a holding time determination step of determining a heating time of the preliminary crucible based on the temperature measured by the temperature sensor;
a solid silicon supply number determination step of determining whether to supply the solid silicon material to the preliminary crucible for a plurality of times based on the temperature measured by the temperature detection sensor; and
a liquid silicon supplying step of supplying silicon melted in the preliminary crucible to the main crucible.

11. The method of claim 10, wherein the solid silicon supply number determination step determines whether the temperature detected by the temperature detection sensor corresponds to the temperature range of the molten silicon, while a solid silicon material is supplied to the preliminary crucible for a predetermined number of times.
